(19) United States
(12) Patent Application Publication
(10) Pub. No.: US 2019/0305128 A1
(43) Pub. Date: Oct. 3, 2019

(54) SEMICONDUCTOR STRUCTURE AND METHOD FOR FORMING THE SAME

(71) Applicant: Vanguard International Semiconductor Corporation, Hsinchu (TW)

(72) Inventors: Ankit KUMAR, Ranchi (IN); Chia-Hao LEE, New Taipei City (TW); Jui-Chun CHANG, Hsinchu City (TW)

(73) Assignee: Vanguard International Semiconductor Corporation, Hsinchu (TW)

(21) Appl. No.: 15/944,419

(22) Filed: Apr. 3, 2018

(51) Int. Cl. H01L 29/78; H01L 29/66

(52) U.S. Cl. CPC H01L 29/7824; H01L 29/66681

(57) ABSTRACT

A semiconductor structure includes an insulating layer, a semiconductor layer, and an epitaxial layer. The insulating layer is disposed on a substrate. The semiconductor layer is disposed on the insulating layer. The semiconductor layer includes a first buried layer and a second buried layer. The first buried layer has a first conductivity type. The second buried layer is disposed over the first buried layer and has a second conductivity type opposite to the first conductivity type. The second buried layer has at least two portions separate from each other. The epitaxial layer is disposed on the semiconductor layer.

### BACKGROUND

### Technical Field

The disclosure relates to a semiconductor structure and more particularly to a semiconductor structure with a substrate.

### Description of the Related Art

In the semiconductor industry, a conventional bulk silicon substrate may be replaced using semiconductor-on-insulator (SOI) technology. A semiconductor-on-insulator (SOI) device includes a buried oxide layer sandwiched between a base layer and a silicon layer. The advantages of the semiconductor-on-insulator (SOI) structure include lower leakage current, higher power efficiency, lower parasitic capacitance, and reduced latch-up effect.

However, semiconductor-on-insulator (SOI) devices may suffer from the backside bias effect when applying backside bias voltage to the handling wafer. The breakdown voltage may drop. To minimize the impact, additional circuits have been added by designers. This may increase the complexity and also limit the range of applications.

Therefore, although existing semiconductor-on-insulator (SOI) devices have generally been adequate for their intended purposes, they have not been entirely satisfactory in all respects and need to be improved. This is especially true for the backside bias effect on the semiconductor-on-insulator (SOI) devices.

### BRIEF SUMMARY

The present disclosure provides a semiconductor structure. The semiconductor structure includes an insulating layer disposed on a substrate. The semiconductor structure further includes a semiconductor layer disposed on the insulating layer. The semiconductor layer includes a first buried layer having a first conductivity type. The semiconductor layer has a second buried layer disposed over the first buried layer with a second conductivity type opposite to the first conductivity type. The second buried layer has at least two portions separate from each other. The semiconductor structure further includes an epitaxial layer disposed on the semiconductor layer.

The present disclosure also provides a method for forming a semiconductor structure. The method for forming a semiconductor structure includes forming an insulating layer disposed on a substrate. The method for forming a semiconductor structure further includes forming a semiconductor layer disposed on the insulating layer. The method for forming a semiconductor structure further includes forming a first buried layer in the semiconductor layer. The first buried layer has a first conductivity type. The method for forming a semiconductor structure further includes forming a second buried layer in the semiconductor layer and over the first buried layer. The second buried layer has a second conductivity type opposite to the first conductivity type, and the second buried layer has at least two portions separate from each other. The method for forming a semiconductor structure further includes forming an epitaxial layer on the semiconductor layer.

A detailed description is given in the following embodiments with reference to the accompanying drawings.

### BRIEF DESCRIPTION OF DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1-8 are cross-sectional representations of various stages of forming a semiconductor structure in accordance with some embodiments.

FIG. 9 is a cross-sectional representation of a semiconductor structure in accordance with some alternative embodiments.

FIG. 10 is a cross-sectional representation of a semiconductor structure in accordance with some other alternative embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Herein, the terms “around,” “about,” “substantial” usually mean within 20% of a given value or range, preferably within 10%, and better within 5%, or 3%, or 2%, or 1%, or 0.5%. It should be noted that the quantity herein is a substantial quantity, which means that the meaning of “around,” “about,” “substantial” are still implied even without specific mention of the terms “around,” “about,” “substantial.”

Although some embodiments are discussed with operations performed in a particular order, these operations may be performed in another logical order. In different embodiments, additional operations can be provided before, during, and/or after the stages described the present disclosure. Some of the stages that are described can be replaced or eliminated for different embodiments. Additional features can be added to the semiconductor structure in the present disclosure. Some of the features described below can be replaced or eliminated for different embodiments.

The embodiments of the present disclosure provide a semiconductor structure with two buried layers. At least one of the buried layers has at least two portions separate from each other. The buried layer may help to reduce the backside bias effect. With separate buried layers, the overall buried layer dopant concentration may be decreased and therefore the breakdown voltage may be improved.

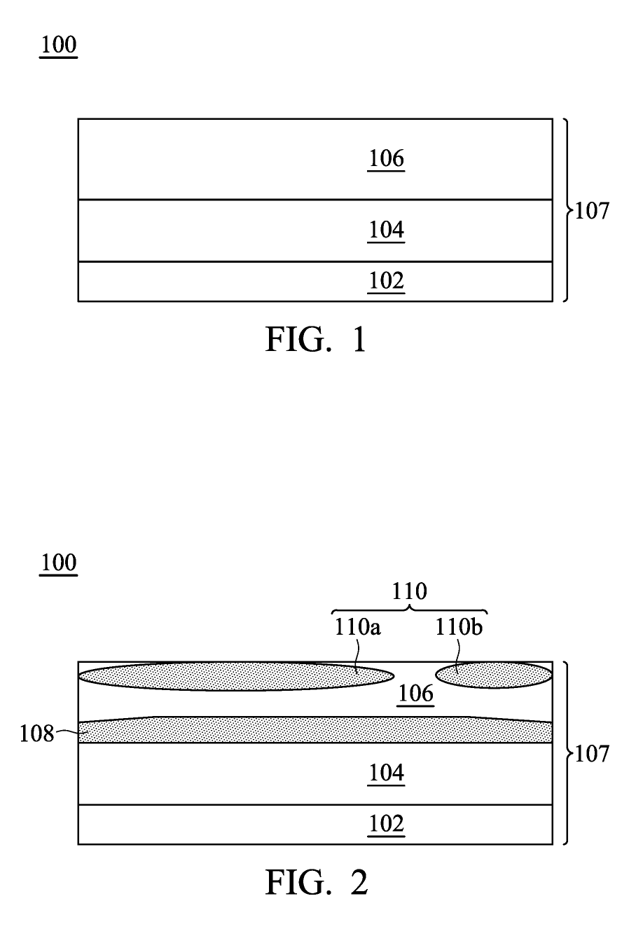

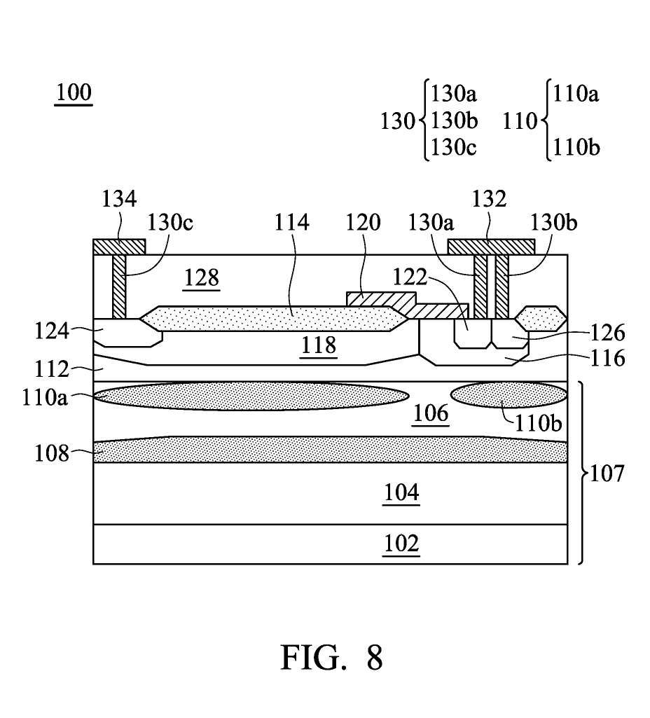

FIGS. 1 to 8 are cross-sectional representations of various stages of forming the semiconductor structure 100 in accordance with some embodiments of the present disclosure. As shown in FIG. 8, the semiconductor structure 100 includes a device such as an LDMOS device formed on a semiconductor-on-insulator (SOI) substrate 107. The semiconductor-on-insulator substrate 107 includes a substrate 102, an insulating layer 104, and a semiconductor layer 106. A first buried layer 108 and a second buried layer 110 are disposed in the semiconductor layer 106. The first buried layer 108 is formed near the bottom surface of the semiconductor layer 106, and the second buried layer 110 is formed near the top surface of the semiconductor layer 106. The second buried layer 110 includes at least two portions 110a and 110b separate from each other by the semiconductor layer 106. The insulating layer 104 in the semiconductor-on-insulator (SOI) substrate 107 may provide isolation to the substrate 102 and the device formed thereon. The first buried layer 108 and the second buried layer 110 may shield the electric field to the bias voltage applied on the substrate 102.

As shown in FIG. 8, a device such as an LDMOS device is formed on the semiconductor-on-insulator (SOI) substrate 107. The LDMOS includes an epitaxial layer 112 formed on the semiconductor-on-insulator substrate 107, a body region 116 formed in the epitaxial layer 112, a drift region 118 formed in the epitaxial layer 112 adjacent to the body region 116, a drain region 124 formed in the drift region 118, a source region 122 formed in the body region 116, isolation features 114 formed on the drift region 118 between the source region 122 and the drain region 124, and a gate structure 120 formed on the epitaxial layer 112 and partially covering the body region 116 and the drift region 118.

The following description describes the manufacturing method of the semiconductor structure 100 in FIG. 8. Referring to FIG. 1, in accordance with some embodiments, a semiconductor-on-insulator substrate 107 is provided. In the semiconductor-on-insulator substrate 107, an insulating layer 104 is formed on a substrate 102, and a semiconductor layer 106 is formed on the insulating layer 104. In some embodiments, the substrate 102 may be a semiconductor substrate such as a Si substrate. Moreover, the semiconductor substrate may also include other elementary semiconductors such as Ge; compound semiconductors such as GaN, SiC, GaAs, GaP, InP, InAs, and/or InSb; alloy semiconductors such as SiGe, GaAsP, AlInAs, AlGaAs, GaTnAs, GaInP, and/or GaInAsP, or a combination thereof. In some embodiments, the substrate 102 has a first conductivity type. In some other embodiments, the substrate 102 has a second conductivity type. The second conductivity type is opposite to the first conductivity type. In some embodiments, the first conductivity type is P-type. For example, the substrate 102 may be a boron-doped substrate. In some other embodiments, the first conductivity type is N-type. For example, the substrate 102 may be a phosphorous-doped or arsenic-doped substrate. In some embodiments, the insulating layer 104 may be a buried oxide layer (BOX).

In some embodiments, the semiconductor-on-insulator substrate 107 may be formed by a separation by implantation of oxygen (SIMOX), a wafer bonding process, an epitaxial layer transfer process, other suitable processes, or a combination thereof. In the separation by implantation of oxygen process, an oxygen ion beam is implanted into a silicon wafer with high energy. The implanted oxygen ion will react with the silicon, and the insulating layer 104 such as an oxide layer is formed below the surface of the silicon wafer by a high-temperature annealing process. The portion of the silicon wafer below the insulating layer is the substrate 102, and the portion of the silicon wafer above the insulating layer is the semiconductor layer 106.

In some other embodiments, the semiconductor-on-insulator substrate 107 may be formed by a wafer bonding process. In the wafer bonding process, the insulating layer 104 such as an oxide layer is formed by directly bonding oxidized silicon with the semiconductor layer 106. Then, the semiconductor layer 106 is thinned before bonding to the substrate 102.

In some other embodiments, the semiconductor-on-insulator substrate 107 may be formed by an epitaxial layer transfer process. In the epitaxial layer transfer process, the semiconductor layer 106 is epitaxially grown on a seed layer (not shown). The insulating layer 104 such as an oxide layer is formed by oxidizing the semiconductor layer 106. After bonding the substrate 102 on the insulating layer 104, the semiconductor layer 106 is split. By transposing the portion with the substrate 102 and the insulating layer 104, a semiconductor-on-insulator substrate 107 is formed.

In some embodiments, the semiconductor layer 106 has a thickness of 1 μm and 15 μm, and the insulating layer 104 has a thickness of between 0.3 μm and 5 μm. If the semiconductor layer 106 and the insulating layer 104 are too thick, the device may not be able to fully deplete and the cost may increase. If the semiconductor layer 106 and the insulating layer 104 are too thin, the breakdown voltage may be worse and the leakage current may increase.

Next, as shown in FIG. 2 according to some embodiments, a first buried layer 108 and a second buried layer 110 are formed in the semiconductor layer 106. The first buried layer 108 is formed near the bottom surface of the semiconductor layer 106, and the second buried layer 110 is formed near the top surface of the semiconductor layer 106. Therefore, the second buried layer 110 is formed over the first buried layer 108. The second buried layer 110 includes at least two portions 110a and 110b separate from each other. In some embodiments, the second buried layers 110a and 110b are separate from each other under the gate structure which will formed thereon later.

In some embodiments, the first buried layer 108 has a first conductivity type. The first conductivity type may be P-type dopant such as B, Ga, Al, In, BF3⁺ ions, or a combination thereof. Alternatively, the first conductivity type may be N-type dopant such as P, As, N, Sb ions, or a combination thereof. The second buried layer 110 has a second conductivity type opposite to the first conductivity type. The dopant concentration of the first buried layer 108 and the second buried layer 110 may be of any range which may be optimized to eliminate the backside bias effect. If the dopant concentration is too high, the breakdown voltage may increase. If the dopant concentration is too low, the backside bias effect may worsen.

In some embodiments, the first buried layer 108 may be formed by a blanket ion implantation process without masks. The second buried layer 110 may be formed by being implanted through a patterned mask (not shown) such as a patterned photoresist or a patterned hard mask having openings that expose the areas to be implanted. Therefore, the separate second buried layers 110a and 110b are formed.

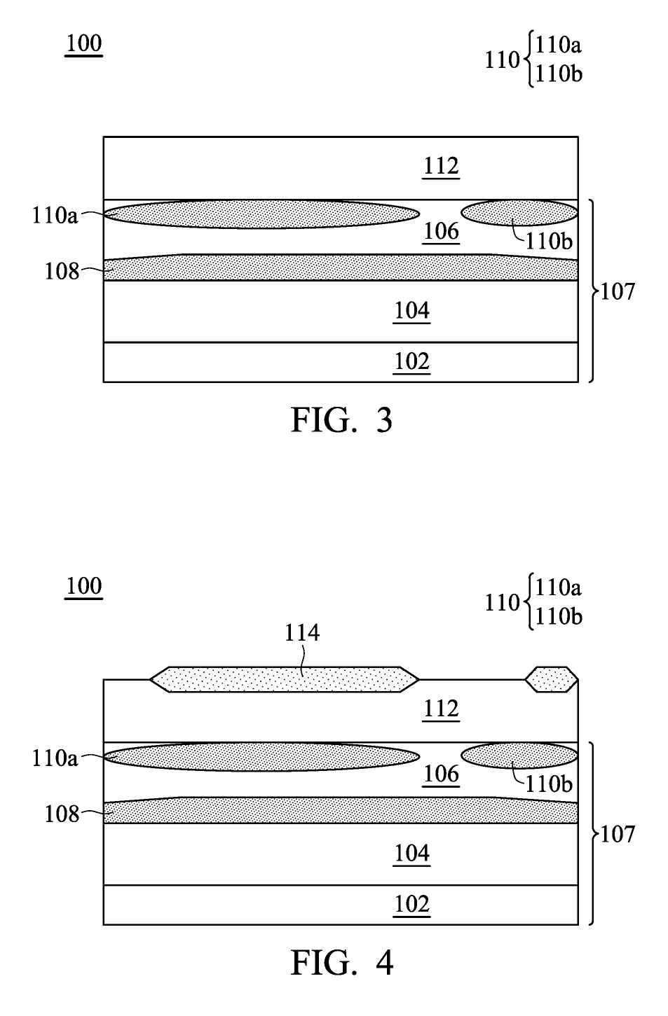

Next, as shown in FIG. 3 according to some embodiments, an epitaxial layer 112 is formed on the semiconductor-on-insulator substrate 107. In some embodiments, the epitaxial layer 112 is made of silicon. In some embodiments, the epitaxial layer 112 has a first conductivity type. In some other embodiments, the epitaxial layer 112 has a second conductivity type. The epitaxial layer 112 may be formed on the semiconductor layer 106 by any suitable process such as molecular-beam epitaxy (MBE), metalorganic chemical vapor deposition (MOCVD), chemical vapor deposition (CVD), hydride vapor phase epitaxy (HVPE), or a combination thereof. The epitaxial layer 112 has a thickness of 2 μm and 15 μm. If the epitaxial layer 112 is too thick, the device may not be able to fully deplete. If the epitaxial layer 112 is too thin, the breakdown voltage may be worse.

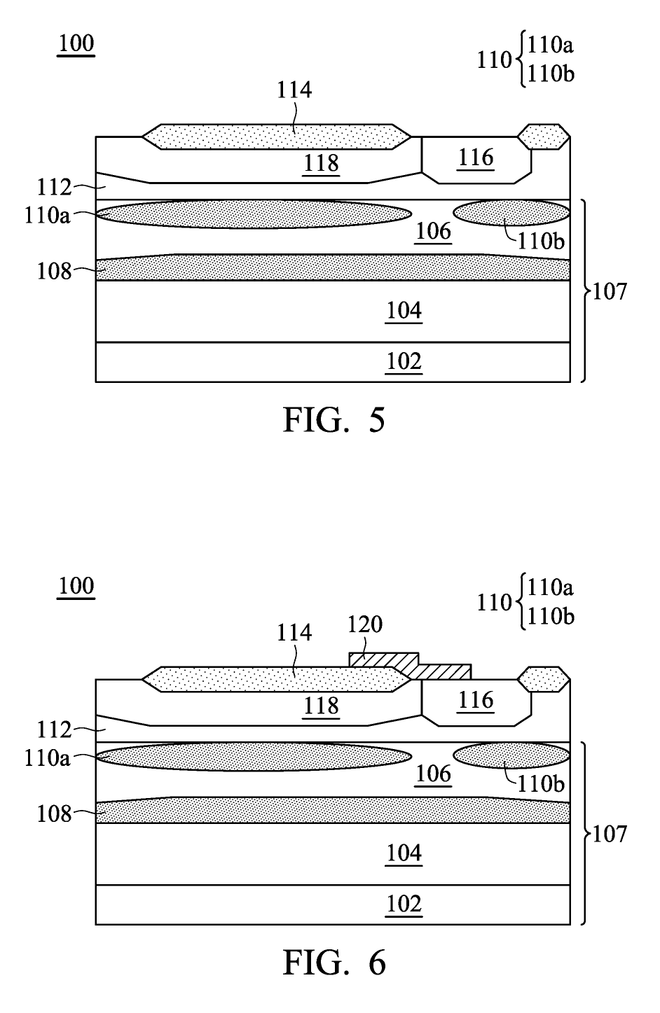

Next, as shown in FIG. 4 according to some embodiments, isolation features 114 are formed embedding in the epitaxial layer 112 near the top surface of the epitaxial layer 112. In some embodiments, the isolation features 114 may be field oxide (FOX). In some embodiments, the isolation features 114 may be local oxidation of silicon (LOCOS) or a shallow trench isolation (STI) structure. The isolation features 114 may be made of silicon oxide, silicon nitride, silicon oxynitride, other applicable dielectric materials, or a combination thereof.

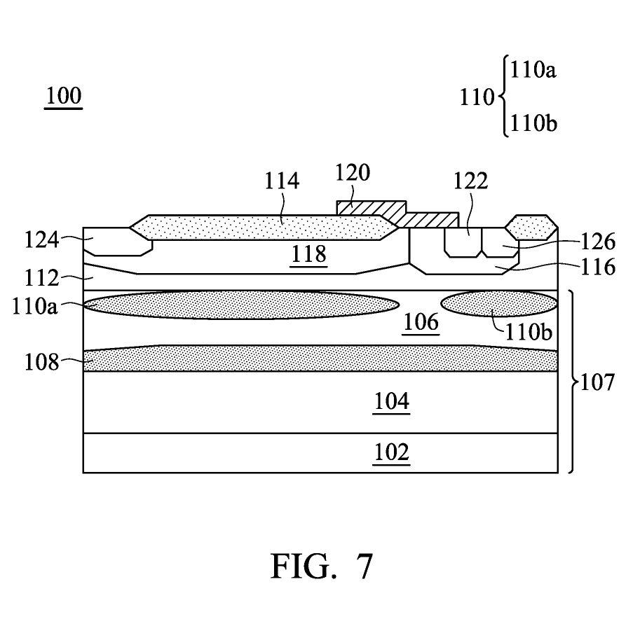

Next, as shown in FIG. 5 according to some embodiments, a body region 116 and a drift region 118 are formed in the epitaxial layer 112 near the top surface of the epitaxial layer 112. The body region 116 and a drift region 118 are formed adjacent to each other. The interface between the body region 116 and the drift region 118 is in the active area of the semiconductor structure 100. In some embodiments, the body region 116 and the drift region 118 are formed by ion implanting the epitaxial layer 112 through individual patterned masks. In some embodiments, the drift region 118 may be formed by one ion implantation process. In some other embodiments, the drift region 118 may be formed by multiple ion implantation processes. In some embodiments, the body region 116 has the second conductivity type, and the drift region 118 has the first conductivity type. The body region 116 and the drift region 118 may have a dopant concentration that is higher than that of the semiconductor layer 112. During the ion implanting process, the dopant may punch through the isolation features 114 and the body region 116 and the drift region 118 may be formed under the isolation features 114.

It should be noted that, in the description above, the isolation features 114 are formed prior to the formation of the body region 116 and the drift region 118. However, the forming sequence is not limited thereto. The body region 116 and the drift region 118 may be formed prior to the formation of the isolation features 114.

Next, as shown in FIG. 6 according to some embodiments, a gate structure 120 is formed on the epitaxial layer 112 partially covering the body region 116 and the drift region 118. The gate structure 120 may extend over the isolation features 114. In some embodiments, the gate structure 120 may include a gate dielectric layer and a gate electrode layer disposed on the gate dielectric layer (not shown). The gate dielectric layer may include silicon oxide, silicon nitride, or silicon oxynitride. The gate dielectric layer may be grown by an applicable oxidation process (such as a dry oxidation process or a wet oxidation process), a deposition process (such as a chemical vapor deposition process), other applicable processes, or a combination thereof. In some embodiments, the gate dielectric layer may be thermally grown by a thermal oxidation process in oxygen-containing ambient or nitrogen-containing ambient (such as NO or N₂O) to form the gate dielectric layer before forming the gate electrode layer. Alternatively, the gate dielectric layer may include a high-k dielectric layer (e.g., the dielectric constant is greater than 3.9) such as hafnium oxide (HfO₂). Alternatively, the high-k dielectric layer may include other high-k dielectrics such as LaO, AlO, ZrO, TiO, Ta₂O₅, Y₂O₃, SrTiO₃, BaTiO₃, BaZrO, HfZrO, HfLaO, HfTaO, HfSiO, HfSiON, HfSiO, LaSiO, AlSiO, BaTiO₃, SrTiO₃, Al₂O₃, other applicable high-k dielectric materials, or a combination thereof. The high-k dielectric layer may be formed by a chemical vapor deposition process (CVD) (e.g., a plasma enhanced chemical vapor deposition (PECVD) process, a metalorganic chemical vapor deposition (MOCVD) process, or a high density plasma chemical vapor deposition (HDPCVD)), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

In some embodiments, the gate electrode layer is formed on the gate dielectric layer. The gate electrode layer may include polysilicon, metal (e.g., tungsten, titanium, aluminum, copper, molybdenum, nickel, platinum, the like, or a combination thereof), metal alloys, metal-nitrides (e.g., tungsten nitride, molybdenum nitride, titanium nitride, and tantalum nitride, the like, or a combination thereof), metal-silicides (e.g., tungsten silicide, titanium silicide, cobalt silicide, nickel silicide, platinum silicide, erbium silicide, the like, or a combination thereof), metal-oxides (e.g., ruthenium oxide, indium tin oxide, the like, or a combination thereof), other applicable materials, or a combination thereof. The gate electrode layer may be formed by forming an electrode material by a chemical vapor deposition (CVD) process (e.g., a low pressure chemical vapor deposition process (LPCVD), or a plasma enhanced chemical vapor deposition process (PECVD)), a physical vapor deposition process (PVD) (e.g., a resistive heating evaporation process, an e-beam evaporation process, or a sputtering process), an electroplating process, an atomic layer deposition process (ALD), other applicable processes, or a combination thereof. The electrode material is then patterned by a photolithography process and an etching process to form a gate electrode.

Next, as shown in FIG. 7, a source region 122, a drain region 124, and a bulk region 126 are formed. The source region 122 and the bulk region 126 are disposed in the body region 116 near the top surface of the epitaxial layer 112, and the source region 122 adjoins the bulk region 126. The drain region 124 is disposed in the drift region 118 near the top surface of the epitaxial layer 112. In some embodiments, the source region 122, the drain region 124, and the bulk region 126 are formed by ion implanting the epitaxial layer 112 through a patterned mask.

In some embodiments, the bulk region 126 has the second conductivity type with a dopant concentration higher than the second conductivity type dopant concentration of the body region 116. The source region 122 and the drain region 124 both have the first conductivity type, and their dopant concentrations are both higher than the first conductivity type dopant concentration of the drift region 118.

Next, as shown in FIG. 8, an interlayer dielectric layer (ILD) 128 covering the semiconductor layer 112 is formed. The interlayer dielectric layer 128 may include one or more single or multiple layers of dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. The low-k dielectric materials may include, but are not limited to, fluorinated silica glass (FSG), hydrogen silsesquioxane (HSQ), carbon doped silicon oxide, amorphous fluorinated carbon, parylene, bis-benzocyclobutenes (BCB), or polyimide. The interlayer dielectric layer 128 may be formed by chemical vapor deposition (CVD) (e.g., a high-density plasma chemical vapor deposition (HDPCVD) process, an atmospheric pressure chemical vapor deposition (APCVD) process, a low-pressure chemical vapor deposition (LPCVD) process, or a plasma enhanced chemical vapor deposition (PECVD) process), a spin-on coating process, other applicable processes, or a combination thereof.

As shown in FIG. 8, according to some embodiments, an interconnect structure is formed. The interconnect structure includes a source electrode 132 and a drain electrode 134 disposed on the interlayer dielectric layer 128, and contact plugs 130 through the interlayer dielectric layer 128. The contact plugs 130 include at least three individual contact plugs 130a, 130b, and 130c. In some embodiments, the source electrode 132 is electrically connected to the source region 122 and the bulk region 126 by the contact plugs 130a and 130b respectively, and the drain electrode 134 is electrically connected to the drain region 124 by the contact plug 130c.

In some embodiments, contact openings may be formed in the interlayer dielectric layer 128 (not shown) by a photolithography process (such as photoresist coating, soft baking, exposure, post-exposure baking, development, other applicable techniques, or a combination thereof) and an etching process (such as a wet etching process, a dry etching process, other applicable techniques, or a combination thereof), other applicable techniques, or a combination thereof. After that, a conductive material is filled in the openings to form the contact plugs 130. In some embodiments, the conductive material of the contact plugs 130 includes metal materials (such as W, Al, or Cu), metal alloys, polysilicon, other applicable conductive materials, or a combination thereof. The contact plugs 130 may be formed by a physical vapor deposition process (PVD) (e.g., evaporation or sputtering), an electroplating process, an atomic layer deposition process (ALD), other applicable processes, or a combination thereof to deposit the conductive materials, and then optionally performing a chemical mechanical polishing (CMP) process or an etching back process to remove excess conductive materials to form the contact plugs 130.

In some embodiments, a barrier layer may be formed on the sidewalls and the bottoms of the openings before filling the conductive material of the contact plugs 130 (not shown) to prevent the conductive material of the contact plugs 130 from diffusing into the interlayer dielectric layer 128. The barrier layer may also serve as an adhesive or glue layer. The material of the barrier layer may be TiN, Ti, Ta, TaN, W, WN, other applicable materials, or a combination thereof. The barrier layer may be formed by depositing the barrier layer materials by a physical vapor deposition process (PVD) (e.g., evaporation or sputtering), an atomic layer deposition process (ALD), an electroplating process, other applicable processes, or a combination thereof.

In some embodiments, the source electrode 132 and the drain electrode 134 are formed on the interlayer dielectric layer 128. In some embodiments, the source electrode 132 and the drain electrode 134 may include Cu, W, Ag, Sn, Ni, Co, Cr, Ti, Pb, Au, Bi, Sb, Zn, Zr, Mg, In, Te, Ga, other applicable metallic materials, an alloy thereof, or a combination thereof. In some embodiments, the source electrode 132 and the drain electrode 134 may include a stacked structure of TiN/AlCu/TiN. In some embodiments, a blanket metal layer is formed on the interlayer dielectric layer 128 (not shown) by a physical vapor deposition process (PVD) (e.g., evaporation or sputtering), an electroplating process, an atomic layer deposition process (ALD), other applicable process, or a combination thereof. After that, the blanket metal layer is patterned by a patterning process to form a first metallization layer. In some embodiments, the patterning process may include a photolithography process (such as photoresist coating, soft baking, exposure, post-exposure baking, development, other applicable techniques, or a combination thereof), an etching process (such as a wet etching process, a dry etching process, other applicable techniques, or a combination thereof), other applicable techniques, or a combination thereof.

In some embodiments, the contact plugs 130, the source electrode 132, and the drain electrode 134 may be formed separately. In some other embodiments, the contact plugs 130, the source electrode 132, and the drain electrode 134 may be formed at the same time by a dual damascene process.

As shown in FIG. 8, the resulting semiconductor structure 100 includes a device such as an LDMOS formed on a semiconductor-on-insulator (SOI) substrate 107. With the first buried layer 108 and the second buried layer 110, the backside bias effect may be eliminated since the charges in the first buried layer 108 and the separate second buried layer 110 may shield the electric field caused by the back bias voltage. The separate second buried layers 110a and 110b may help to lower the overall second conductivity type dopant concentration of the second buried layer 110 and may help to sustain the breakdown voltage while eliminating the backside bias effect. Separate buried layers may provide more process flexibility with just one additional mask, therefore the breakdown voltage may be improved in an easy and cost effective manner.

As shown in FIG. 8, since a breakdown is most likely to occur under the gate structure 120, the second buried layers 110a and 110b are separate from each other under the gate structure 120 to lower the dopant concentration of the second buried layer 110 under the gate structure 120.

It should be noted that, although the semiconductor structure 100 in FIGS. 1 to 8 is an LDMOS device on a SOI substrate, embodiments of the disclosure are not limited thereto. In some embodiments, the semiconductor structure 100 may include devices such as DDMOS, LDMOS, other suitable devices, or a combination thereof. In addition, the substrate may include a bulk substrate such an element semiconductor substrate, a compound semiconductor substrate, an alloy semiconductor substrate, other suitable substrates, or a combination thereof.

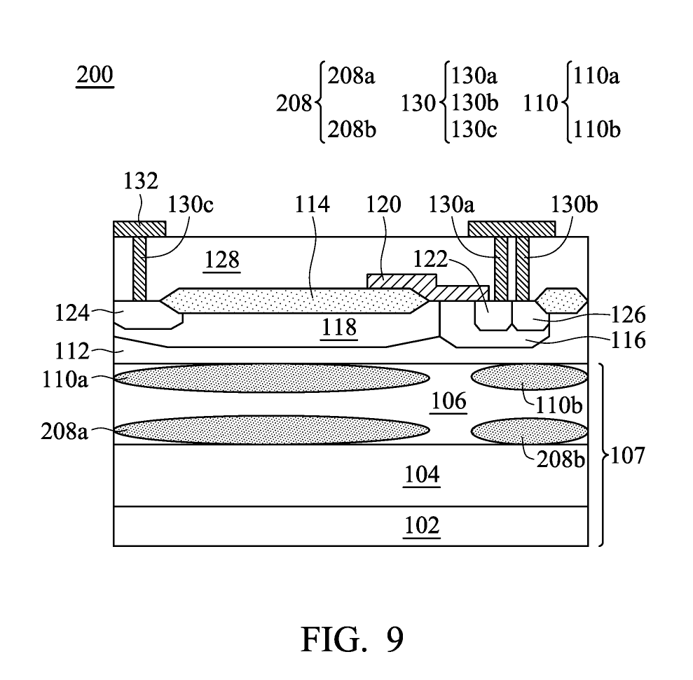

FIG. 9 is a cross-sectional representation of a semiconductor structure 200 in accordance with some alternative embodiments. Some processes or devices are the same as, or similar to, those described in the embodiments above, and therefore the reference numerals and/or letters may be repeated. For the purpose of brevity, the descriptions of these processes and devices are not repeated herein. The difference from the embodiments described above is that, as shown in FIG. 9, the first buried layer 208 includes at least two portions 208a and 208b separate from each other.

In some embodiments, the first buried layer 208 may be formed by an ion implantation process with the same mask used in the ion implantation process of the second buried layer 110. Therefore, the separate first buried layer 208a and 208b and the separate second buried layers 110a and 110b are vertically aligned.

As shown in FIG. 9, the semiconductor structure 200 includes a device such as an LDMOS is formed on a semiconductor-on-insulator (SOI) substrate 107. With the first buried layer 108 and the second buried layer 110, the backside bias effect may be eliminated since the charges in the separate first buried layer 208 and the separate second buried layer 110 may shield the electric field caused by the back bias voltage. Compared to the embodiment shown in FIG. 8, the separate first buried layers 208a and 208b and the second buried layer 110a and 110b may help to further lower the overall dopant concentration, which may help to sustain the breakdown voltage while eliminating the backside bias effect. Since the first buried layer 208 and the second buried layer 110 are formed by the same mask, there may be more process flexibility with just one additional mask.

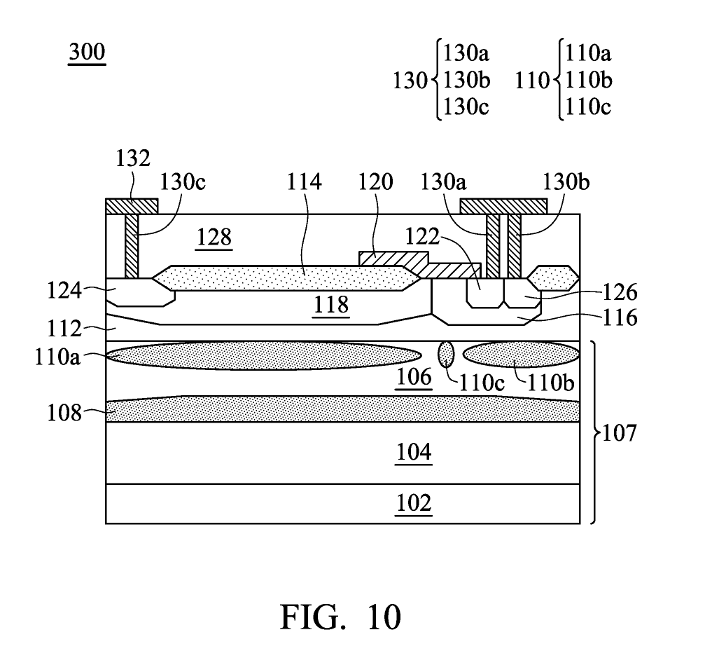

FIG. 10 is a cross-sectional representation of a semiconductor structure 300 in accordance with some other alternative embodiments. Some processes or devices are the same as, or similar to, those described in the embodiments above, and therefore the reference numerals and/or letters may be repeated. For the purpose of brevity, the descriptions of these processes and devices are not repeated herein. The difference from the embodiments described above is that, as shown in FIG. 10, the second buried layer 110 includes at least three portions 110a, 110b, and 110c separate from each other. The second buried layer 110 may be formed by being implanted through a patterned mask (not shown) such as a patterned photoresist or a patterned hard mask having openings that expose the areas to be implanted. Therefore, the separate second buried layers 110a, 110b, and 110c are formed.

As shown in FIG. 10, the semiconductor structure 100 includes a device such as an LDMOS is formed on a semiconductor-on-insulator (SOI) substrate 107. With the first buried layer 108 and the second buried layer 110, the backside bias effect may be eliminated since the charges in the first buried layer 108 and the separate second buried layer 110 may shield the electric field caused by the back bias voltage. Compared to the embodiment shown in FIG. 8, the separate second buried layers 110a, 110b, and 110c may help to further lower the overall second conductivity type dopant concentration of the second buried layer 110 and may help to sustain the breakdown voltage while eliminating the backside bias effect. Separate buried layers may provide more process flexibility with just one additional mask. Different numbers of separate second buried layer 110 may also provide more flexibility of improving breakdown voltage and backside bias effect.

It should be noted that, in FIG. 10, there are three separate second buried layers 110a, 110b, and 110c. However, the present disclosure is not limited thereto. Depending on the demands of the process, more than three separate second buried layers may be formed in the semiconductor layer 106.

As mentioned above, in the present disclosure, separate buried layers are disposed in the substrate. When a back bias voltage is applied on the back side, the buried layers may help to eliminate the backside bias effect. With separate buried layers, the overall dopant concentration may be lowered and the breakdown voltage may be sustained while eliminating the backside bias effect. Only one extra mask is needed to form separate buried layer, and therefore the production cost and time may not be impacted too much.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
an insulating layer disposed on a substrate;
a semiconductor layer disposed on the insulating layer, comprising:
a first buried layer having a first conductivity type; and
a second buried layer stacked over the first buried layer along a direction perpendicular to an interface between the substrate and the insulating layer and spaced apart from the first buried layer, having a second conductivity type opposite to the first conductivity type;
wherein the second buried layer has at least two portions separate from each other; and
an epitaxial layer disposed on the semiconductor layer,
wherein the semiconductor layer is spaced apart from the substrate by the insulating layer.

2. The semiconductor structure as claimed in claim 1, further comprising:
a body region disposed in the epitaxial layer, having the second conductivity type;
a drift region disposed in the epitaxial layer adjacent to the body region, having the first conductivity type;
a drain region disposed in the drift region, having the first conductivity type;
a source region disposed in the body region, having the first conductivity type;
an isolation feature disposed on the drift region between the source region and the drain region;
a gate structure disposed on the epitaxial layer and partially covering the body region and the drift region.

3. The semiconductor structure as claimed in claim 2, wherein the second buried layer has at least two portions separate from each other under the gate structure.

4. The semiconductor structure as claimed in claim 2, further comprising:
a bulk region disposed in the body region and adjacent to the source region, having the second conductivity type.

5. The semiconductor structure as claimed in claim 1, wherein the second buried layer has at least three portions separate from each other.

6. The semiconductor structure as claimed in claim 1, wherein the first buried layer has at least two portions separate from each other.

7. The semiconductor structure as claimed in claim 6, wherein the first buried layer and the second buried layer are vertically aligned to each other.

8. The semiconductor structure as claimed in claim 1, wherein the semiconductor layer has a thickness of between 1 μm and 15 μm, and the insulating layer has a thickness of between 0.3 μm and 5 μm.

9. The semiconductor structure as claimed in claim 1, wherein the epitaxial layer has a thickness of between 2 μm and 15 μm.

10. A method for forming a semiconductor structure, comprising:
forming an insulating layer disposed on a substrate;
forming a semiconductor layer disposed on the insulating layer;
forming a first buried layer in the semiconductor layer, wherein the first buried layer has a first conductivity type; and
forming a second buried layer in the semiconductor layer and over the first buried layer, wherein the second buried layer is stacked over the first buried layer along a direction perpendicular to an interface between the substrate and the insulating layer and spaced apart from the first buried layer, the second buried layer has a second conductivity type opposite to the first conductivity type, and the second buried layer has at least two portions separate from each other; and
forming an epitaxial layer on the semiconductor layer,
wherein the semiconductor layer is spaced apart from the substrate by the insulating layer.

11. The method for forming a semiconductor structure as claimed in claim 10, further comprising:
forming a body region in the epitaxial layer, wherein the body region has the second conductivity type;
forming a drift region in the epitaxial layer adjacent to the body region, wherein the drift region has the first conductivity type;
forming a drain region in the drift region, wherein the drain region has the first conductivity type;
forming a source region in the body region, wherein the source region has the first conductivity type;
forming an isolation feature on the drift region between the source region and the drain region; and
forming a gate structure on the epitaxial layer and partially covering the body region and the drift region.

12. The method for forming a semiconductor structure as claimed in claim 11, wherein the second buried layer has at least two portions separate from each other under the gate structure.

13. The method for forming a semiconductor structure as claimed in claim 11, further comprising:
forming a bulk region disposed in the body region and adjacent to the source region, wherein the bulk region has the second conductivity type.

14. The method for forming a semiconductor structure as claimed in claim 10, wherein the second buried layer has at least three portions separate from each other.

15. The method for forming a semiconductor structure as claimed in claim 10, wherein the first buried layer has at least two portions separate from each other.

16. The method for forming a semiconductor structure as claimed in claim 15, wherein the first buried layer and the second buried layer are formed by a single mask.

17. The method for forming a semiconductor structure as claimed in claim 10, wherein the semiconductor layer has a total thickness of between 1 μm and 15 μm, and the insulating layer has a thickness of between 0.3 μm and 5 μm.

18. The method for forming a semiconductor structure as claimed in claim 10, wherein the epitaxial layer has a thickness of between 2 μm and 15 μm.
